(19) United States
(12) Patent Application Publication
(10) Pub. No.: US 2009/0315651 A1
(43) Pub. Date: Dec. 24, 2009

(54) WIRELESS TRANSMISSION PACKAGE DEVICE

(75) Inventor: SHENG MING DENG, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: WAVERAY TECHNOLOGY CORP., HSINCHU COUNTY (TW)

(21) Appl. No.: 12/485,339

(22) Filed: Jun. 16, 2009

(30) Foreign Application Priority Data
Jun. 18, 2008 (TW) 097210770

(51) Int. Cl. H03H 2/00

(52) U.S. Cl. 333/24 R

(57) ABSTRACT

A wireless transmission package device comprises a first signal pin, a second signal pin; and a third signal pin. The second signal pin and the third signal form a signal input-output transmission channel when the first signal pin is not connected to an external load, whereas the second signal pin and the first signal pin form the signal input-output transmission channel when the first signal pin is connected to an external load.

### BACKGROUND OF THE INVENTION

1. Field of the Invention

The present invention relates to a wireless transmission package device, and more specifically, to a wireless transmission package device capable of switching input/output channels.

2. Description of the Related Art

In the past, apart from those engaged in topographic survey, engineering or academic research fields, most people were not familiar with the Global Positioning System (GPS). In today's world of increasingly busy city traffic complicated by construction and navigational challenges of commuters and travelers, there is a rapidly growing market for GPS products capable of providing abundant navigation information to enhance driving convenience, and the GPS-related product market has become prosperous.

With the trend of small size of electronic products and the use of highly integrated, mixed IC serving as RF front end, current GPS designs are highly compact and a GPS system may include a core processor, embedded memory chips and small electronic devices.

Various solutions for GPS devices have some advantages or disadvantages while the GPS antenna and receiver modules play key roles in the navigation system. The GPS antenna and the receiver must function well together to provide superior features in a GPS navigation apparatus.

The antenna designed for GPS use must be easy to use, accurate, in accordance with quantitative standards, and feature sensitive positioning and low power consumption. These demands significantly affect the GPS design.

The antenna may be embedded in the receiver to meet reduced size requirements. As a result, however, the sensitivity is decreased. Therefore, GPS devices must be improved in terms of both signal receiving and transmission and operation convenience.

### SUMMARY OF THE INVENTION

The present invention provides a wireless transmission package device capable of switching input/output channels, thereby improving both transmission signal quality and operation convenience, and thus increasing application value and practicality.

In accordance with the present invention, a wireless transmission package device comprises a first signal pin, a second signal pin and a third signal pin. The second signal pin and the third signal pin form a signal input-output transmission channel when the first signal pin is not connected to an external load, whereas the second signal pin and the first signal pin form a signal input-output transmission channel when the first signal pin is connected to an external load.

In an embodiment, the three signal pins may include a signal input pin and two signal output pins. When a signal output pin (e.g., the first signal pin) is not connected to a load (e.g., an external antenna), signals are inputted through the signal input pin (e.g., the second signal pin) and outputted through another signal output pin (e.g., the third signal pin). When a first signal output pin is connected to a load, signal transmission will automatically switch to go through the first signal output pin.

The wireless transmission package device may further include a supply voltage (Vcc) pin and a grounding pin. In an embodiment, a capacitor and an inductance are electrically coupled to the first output pin, and the capacitor and the inductance are connected to the load. The capacitor and the inductance can be externally or internally integrated with the wireless transmission package device.

The wireless transmission package device can be applied to GPS, digital video broadcasting (DVB), or the like.

### BRIEF DESCRIPTION OF THE DRAWINGS

The invention will be described according to the appended drawings in which:

FIG. 1 illustrates a wireless transmission package device in accordance with a first embodiment of the present invention; and

FIG. 2 illustrates a wireless transmission package device in accordance with a second embodiment of the present invention.

### DETAILED DESCRIPTION OF THE INVENTION

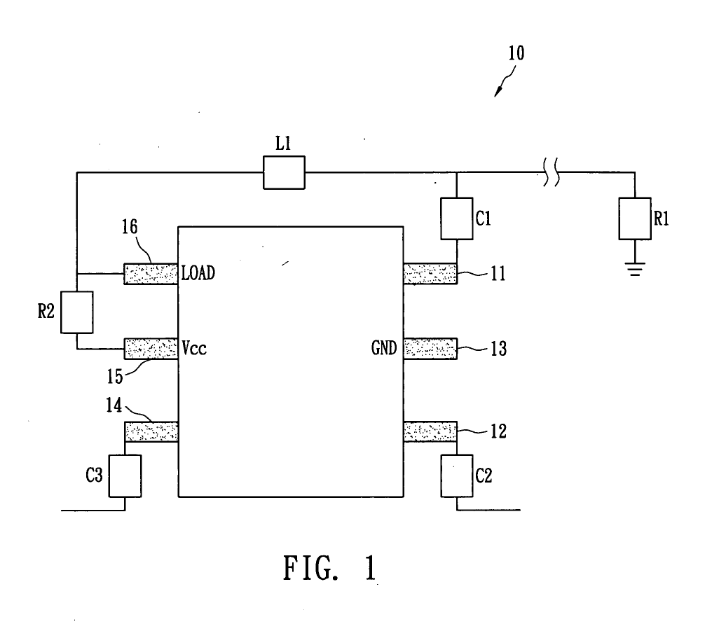

FIG. 1 illustrates a wireless transmission package device in accordance with a first embodiment of the present invention. A wireless transmission package device 10 includes baseband and radio frequency (RF) circuits and 6 pins. The baseband and RF circuits can be made into two chips or an integrated chip. Regardless of what type of chip is used, the single chip or multiple chips including baseband and RF circuits are packaged to form a single wireless transmission package device 10.

The wireless transmission package device 10 includes a signal pin 11, a signal pin 12, a grounding (GND) pin 13, a signal pin 14, a supply voltage (Vcc) pin 15 and a loading pin 16. The signal pins 11, 12 and 14 are respectively connected to capacitors C1, C2 and C3.

In an embodiment, when the signal pin 11 is not connected to a load R1, signals are inputted at the signal pin 14 and outputted at the signal pin 12; however, when the signal pin 11 is connected to the load R1, signals are automatically switched to be outputted at signal pin 11. The load R1 may further be electrically coupled to an inductance L1, and the supply voltage pin 15 and the load pin 16 are connected to a load R2 and electrically connected to the inductance L1. The supply voltage pin 15 receives Vcc DC voltage to control baseband and RF circuits.

As mentioned above, when the wireless transmission package device is connected to a load, the output signal pin will be switched automatically. In an embodiment, the wireless transmission package device 10 is a GPS package device and the signal pin 12 is connected to a GPS apparatus's internal antenna for obtaining basic signal transmission function. When an external antenna R1, i.e., a load, is inserted into the GPS apparatus, the antenna R1 will be electrically connected to the signal pin 11 and the signal transmission will be outputted through signal pin 11 instead of signal pin 12. Therefore, if the internal antenna's signal receiving performance is not good, signal transmission can be improved by using the external antenna R1.

In practice, the signal pins 11, 12 and 14 may be adjusted to one-input and two-output or two-input and one-output as desired, i.e., the pins are not limited to be input or output. For instance, when transmitting signals, the signal pin 14 is an input, and the signal pins 11 and 12 are switched as an output depending on whether the load R1 is connected. When receiving signals, the signal pins 11 and 12 are switched as an input depending on whether the load R1 is connected, and the signal pin 14 is an output.

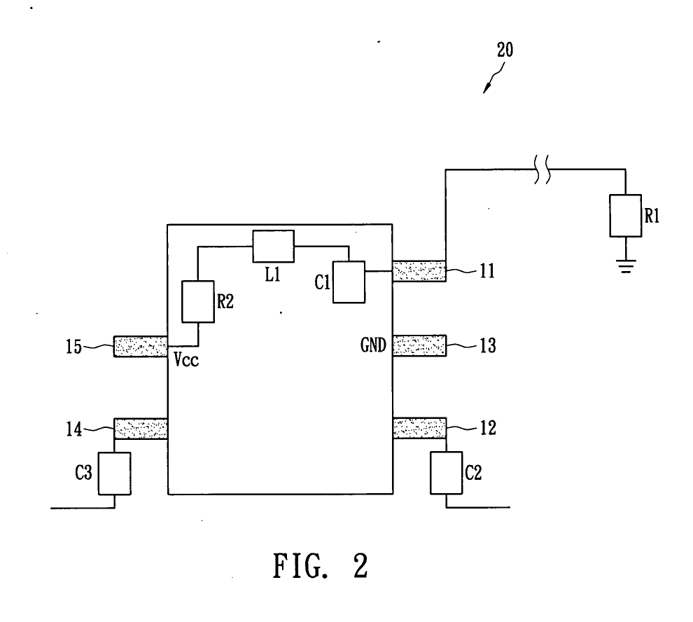

FIG. 2 illustrates a wireless transmission package device in accordance with a second embodiment of the present invention. In comparison with FIG. 1, the wireless transmission package device 20 includes five pins, and the load pin is omitted. The inductance L1, the capacitor C1 and the load R2 are embedded into the wireless transmission package device 20. Likewise, the pins can be either input pins or output pins according to receiving and transmission requirements.

In addition, the number of signal pins such as pins 11 and 12 in FIG. 1 is not limited to two; three or four signal pins also can be used. When an external load is connected to a signal pin, signal transmission will go through the signal pin connected to the external load instead of the pin 12. As a result, multiple pins serving as external loads can be provided, thereby providing various functions and increasing operation convenience.

The wireless transmission package device can automatically switch output pins in response to the connection of a load, and is of small size and low cost. Therefore, the wireless transmission package device is very suitable for being applied to current wireless transmission electronic apparatus.

The above-described embodiments of the present invention are intended to be illustrative only. Numerous alternative embodiments may be devised by those skilled in the art without departing from the scope of the following claims.

What is claimed is:

1. A wireless transmission package device, comprising:
a first signal pin;
a second signal pin; and
a third signal pin;
wherein the second signal pin and the third signal pin form an input-output signal transmission channel when the first signal pin is not connected to an external load, whereas the second signal pin and the first signal pin form the input-output signal transmission channel when the first signal pin is connected to an external load.

2. The wireless transmission package device of claim 1, wherein the input-output signal transmission channel is switched automatically when the first signal pin is connected to the external load.

3. The wireless transmission package device of claim 1, wherein the external load is an external antenna for being connected to the wireless transmission package device.

4. The wireless transmission package device of claim 1, further comprising a supply voltage pin.

5. The wireless transmission package device of claim 4, further comprising a load pin and a load connected to the supply voltage pin and the load pin.

6. The wireless transmission package device of claim 1, further comprising a grounding pin.

7. The wireless transmission package device of claim 1, wherein the first signal pin is electrically coupled to a capacitor and an inductance, and the capacitor and the inductance are electrically connected to the external load when the first signal pin is connected to the external load.

8. The wireless transmission package device of claim 1, further comprising a capacitor and an inductance electrically coupled to the first signal pin, the capacitor and the inductance being embedded in the wireless transmission package device, and the capacitor and the inductance being electrically connected to the external load when the first signal pin is connected to the external load.

9. The wireless transmission package device of claim 1, further comprising a supply voltage pin and an internal load, the internal load being electrically coupled to the supply voltage pin, the capacitor and the inductance and embedded in the wireless transmission package device.

10. The wireless transmission package device of claim 1, further comprising at least one signal pin that performs as the first signal pin does.
